(19) United States
(12) Patent Application Publication
(10) Pub. No.: US 2024/0304775 A1
(43) Pub. Date: Sep. 12, 2024

(54) DISPLAY DEVICE AND ELECTRONIC APPARATUS

(71) Applicant: SEIKO EPSON CORPORATION, Tokyo (JP)

(72) Inventors: Takashi MIYATA, SHIOJIRI-SHI (JP); Yoji KITANO, CHINO-SHI (JP)

(73) Assignee: SEIKO EPSON CORPORATION, Tokyo (JP)

(21) Appl. No.: 18/597,930

(22) Filed: Mar. 7, 2024

(30) Foreign Application Priority Data
Mar. 10, 2023 (JP) 2023-037671

(51) Int. Cl. H01L 33/62; H01L 25/075; H01L 25/16

(52) U.S. Cl. CPC H01L 33/62; H01L 25/0753; H01L 25/167

(57) ABSTRACT

A display device includes: a driving circuit provided at a first substrate and configured to drive a first light-emitting element and a second light-emitting element; a first insulation section having elasticity and provided between the first substrate and the first light-emitting element; a second insulation section having elasticity and provided between the first substrate and the second light-emitting element; a first conductive layer provided between the first insulation section and the first light-emitting element, the first conductive layer being configured to be electrically coupled to the driving circuit and be pressed against the first light-emitting element; a second conductive layer provided between the second insulation section and the second light-emitting element, the second conductive layer being configured to be electrically coupled to the driving circuit and be pressed against the second light-emitting element; and a coupling portion configured to couple the first substrate and a second substrate.

The present application is based on, and claims priority from JP Application Serial Number 2023-037671, filed on Mar. 10, 2023, the disclosure of which is hereby incorporated by reference herein in its entirety.

### BACKGROUND

### 1. Technical Field

The present disclosure relates to a display device and an electronic apparatus.

### 2. Related Art

A light-emitting element such as a light emitting diode (LED) is applied to a light source of a display device.

For example, JP-A-2018-185515 describes a micro LED display device including: a micro LED panel including a plurality of micro LED pixels; a CMOS backplane including a plurality of CMOS cells; and a bump that electrically couples the CMOS cells and the micro LED pixels.

In the micro LED display device as described above, when heights of the plurality of micro LED pixels vary, a failure occurs in electrical coupling between the CMOS cell and the micro LED pixel.

### SUMMARY

An aspect of a display device according to the present disclosure includes a first substrate, a second substrate disposed so as to be opposed to the first substrate, a first light-emitting element and a second light-emitting element provided between the first substrate and the second substrate, a driving circuit provided at the first substrate and configured to drive the first light-emitting element and the second light-emitting element, a first insulation section having elasticity and provided between the first substrate and the first light-emitting element, a second insulation section having elasticity and provided between the first substrate and the second light-emitting element, a first conductive layer provided between the first insulation section and the first light-emitting element, the first conductive layer being configured to be electrically coupled to the driving circuit and be pressed against the first light-emitting element by the first insulation section, a second conductive layer provided between the second insulation section and the second light-emitting element, the second conductive layer being configured to be electrically coupled to the driving circuit and be pressed against the second light-emitting element by the second insulation section, and a coupling portion configured to couple the first substrate and the second substrate.

An aspect of an electronic apparatus according to the present disclosure includes the aspect of the display device described above.

### BRIEF DESCRIPTION OF THE DRAWINGS

FIG. 1 is a plan view schematically illustrating a display device according to the present embodiment.

FIG. 2 is a plan view schematically illustrating a printed wired board of the display device according to the present embodiment.

FIG. 3 is an equivalent circuit diagram concerning driving a light-emitting element of the display device according to the present embodiment.

FIG. 4 is a cross-sectional view schematically illustrating the display device according to the present embodiment.

FIG. 5 is a cross-sectional view schematically illustrating the display device according to the present embodiment.

FIG. 6 is a cross-sectional view schematically illustrating a step of manufacturing the display device according to the present embodiment.

FIG. 7 is a plan view schematically illustrating a display device according to a first modification example of the present embodiment.

FIG. 8 is a cross-sectional view schematically illustrating the display device according to the first modification example of the present embodiment.

FIG. 9 is a plan view schematically illustrating a display device according to a second modification example of the present embodiment.

FIG. 10 is a perspective view schematically illustrating an insulation section and a conductive layer of a display device according to a third modification example of the present embodiment.

FIG. 11 is a perspective view schematically illustrating a head-mounted display according to the present embodiment.

FIG. 12 is a diagram schematically illustrating an image forming device and a light-guiding device of the head-mounted display according to the present embodiment.

### DESCRIPTION OF EMBODIMENTS

Below, a preferred embodiment of the present disclosure will be described in detail with reference to the drawings. Note that the embodiment described below does not unduly limit the content of the present disclosure described in the claims. In addition, not all the configurations described below are essential constituent elements of the present disclosure.

### 1. Display Device

### 1.1. Overall Configuration

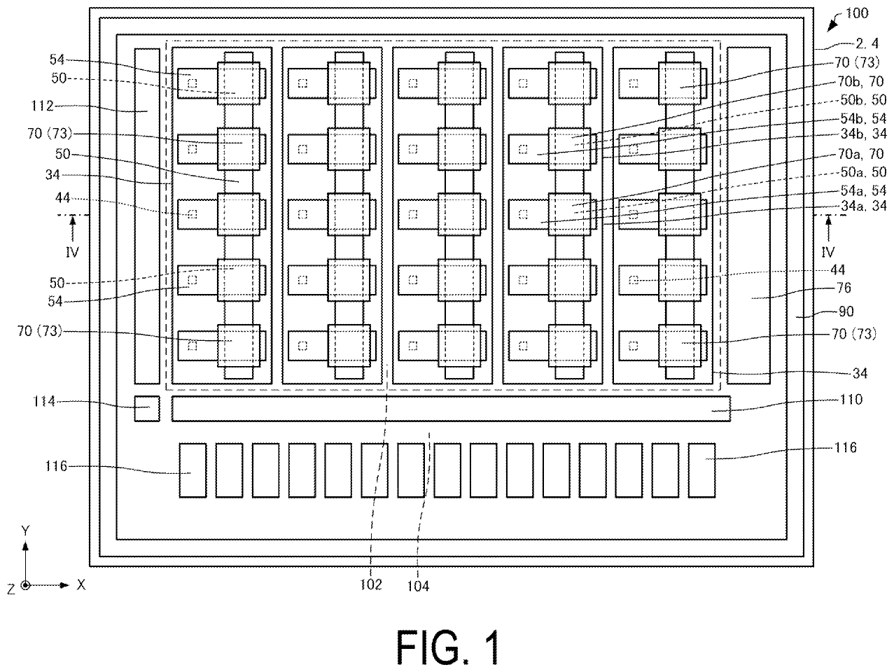

First, a display device according to the present embodiment will be described with reference to the drawings. FIG. 1 is a plan view schematically illustrating a display device 100 according to the present embodiment. Note that, an X-axis, a Y-axis, and a Z-axis are illustrated in FIG. 1 as three axes orthogonal to each other.

The display device 100 is a device configured to display an image. Note that the image includes an image only containing character information. The display device 100 is a micro display favorably used, for example, in a head-mounted display or the like.

The display device 100 includes a display region 102 configured to display an image and a peripheral area 104 surrounding the display region 102 as viewed from the Z-axis direction, as illustrated in FIG. 1. The planar-view shape of the display region 102 is, for example, a quadrilateral shape.

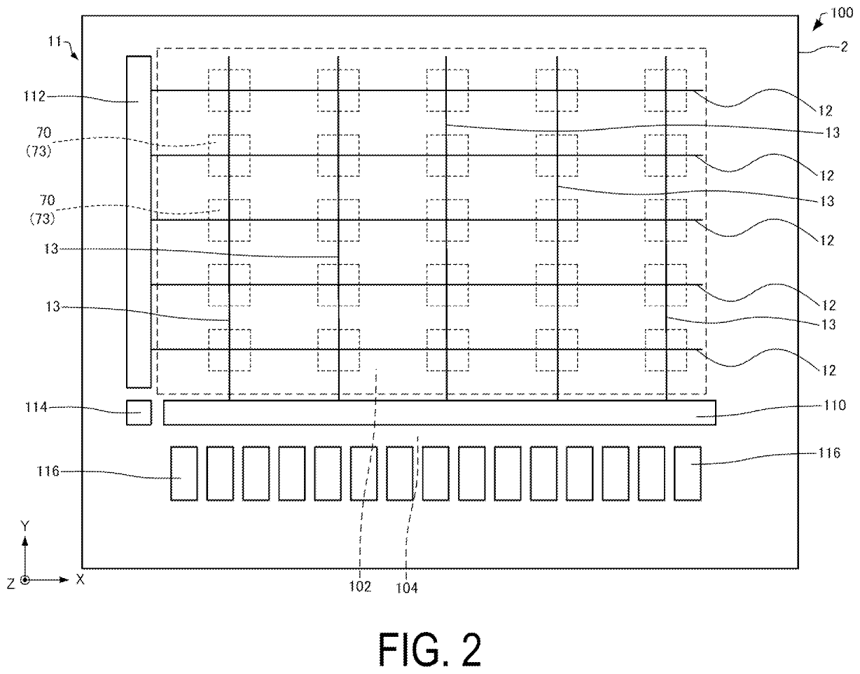

The display device 100 includes a plurality of light-emitting elements 70. The light-emitting elements 70 are provided at the display region 102. In the example illustrated in the drawing, light-emitting layers 73 of the plurality of light-emitting elements 70 are arranged in a matrix manner in the X-axis direction and the Y-axis direction. The light-emitting element 70 constitutes a pixel. The pixel is a minimum unit in displaying an image. Note that, in FIG. 1, the light-emitting layer 73 of the light-emitting element 70 is illustrated as the light-emitting element 70, for the purpose of convenience. This similarly applies to FIGS. 2, 7, and 9 that will be described later.

The display device 100 includes a printed wired board 2 and an element substrate 4. The printed wired board 2 and the element substrate 4 are stacked in the Z-axis direction. The printed wired board 2 and the element substrate 4 overlap with each other as viewed from the Z-axis direction.

The printed wired board 2 includes, for example, a data line driving circuit 110, a scanning line drive circuit 112, a control circuit 114, and an external terminal 116. The data line driving circuit 110, the scanning line drive circuit 112, the control circuit 114, and the external terminal 116 are provided in the peripheral area 104. The data line driving circuit 110 and the scanning line drive circuit 112 are configured to control driving of the light-emitting element 70. The control circuit 114 controls displaying of an image. The control circuit 114 is supplied with image data from an upper circuit that is not illustrated. The control circuit 114 supplies the data line driving circuit 110 and the scanning line drive circuit 112 with various types of signals based on the image data. The external terminal 116 includes a plurality of external terminals. Although illustration is not given, the external terminals 116 are coupled to flexible printed circuits (FPC) substrates or the like electrically coupled to upper circuits. A power-supply circuit that is not illustrated is electrically coupled to the printed wired board 2.

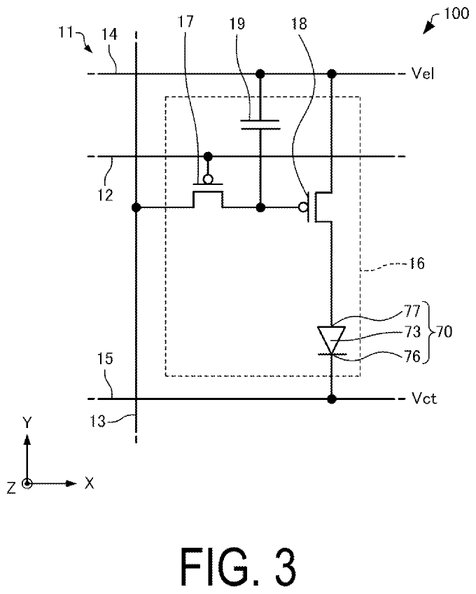

FIG. 2 is a plan view schematically illustrating the printed wired board 2. FIG. 3 is an equivalent circuit diagram concerning driving the light-emitting element 70.

As illustrated in FIGS. 2 and 3, the printed wired board 2 includes a driving circuit 11 configured to drive the light-emitting element 70. The driving circuit 11 includes, for example, a scanning line 12, a data line 13, a first power supplying line 14, a second power supplying line 15, and a pixel circuit 16.

The scanning line 12 is coupled to the scanning line drive circuit 112. The scanning line 12 extends, for example, in the X-axis direction. The scanning line 12 includes a plurality of scanning lines. The plurality of scanning lines 12 are arranged in the Y-axis direction, for example.

The data line 13 is coupled to the data line driving circuit 110. The data line 13 extends, for example, in the Y-axis direction. The data line 13 includes a plurality of data lines. The plurality of data lines 13 are arranged in the X-axis direction, for example.

The first power supplying line 14 is electrically coupled to a second electrode 77 of the light-emitting element 70 through the pixel circuit 16, as illustrated in FIG. 3. From a power-supply circuit that is not illustrated, the first power supplying line 14 is supplied with a power-supply potential Vel at the high side.

The second power supplying line 15 is electrically coupled to a first electrode 76 of the light-emitting element 70 through the pixel circuit 16. From a power-supply circuit that is not illustrated, the second power supplying line 15 is supplied with a power-supply potential Vct at the lower side. Note that the power supplying line 14 or 15 is not illustrated in FIG. 2 for the purpose of convenience.

A plurality of the pixel circuits 16 are provided so as to correspond to the plurality of light-emitting elements 70. The pixel circuit 16 includes, for example, a switching transistor 17, a driving transistor 18, and a retention capacitor 19. The gate of the switching transistor 17 is electrically coupled to the scanning line 12. Either the source or the drain of the switching transistor 17 is electrically coupled to the data line 13, and the other one is electrically coupled to the gate of the driving transistor 18. Either the source or the drain of the driving transistor 18 is electrically coupled to the first power supplying line 14, and the other one is electrically coupled to the second electrode 77. One electrode of the retention capacitor 19 is electrically coupled to the gate of the driving transistor 18, and the other electrode is electrically coupled to the first power supplying line 14.

In the pixel circuit 16, when the scanning line drive circuit 112 turns a scanning signal into “active” to select a scanning line 12, the switching transistor 17 provided at the selected light-emitting element 70 is made ON. Then, a data signal is supplied from the data line 13 to the driving transistor 18 corresponding to the selected scanning line 12. The driving transistor 18 supplies the light-emitting element 70 with a potential of the supplied data signal, that is, a current corresponding to a potential difference between the gate and the source. Thus, the light-emitting element 70 emits light with brightness corresponding to the magnitude of the current supplied from the driving transistor 18. When the scanning line drive circuit 112 cancels the selection of the scanning line 12 to turn the switching transistor 17 OFF, the potential at the gate of the driving transistor 18 is retained by the retention capacitor 19. Thus, even after the switching transistor 17 is turned OFF, the light-emitting element 70 maintains emission of light of the light-emitting element 70.

### 1.2. Printed Wired Board

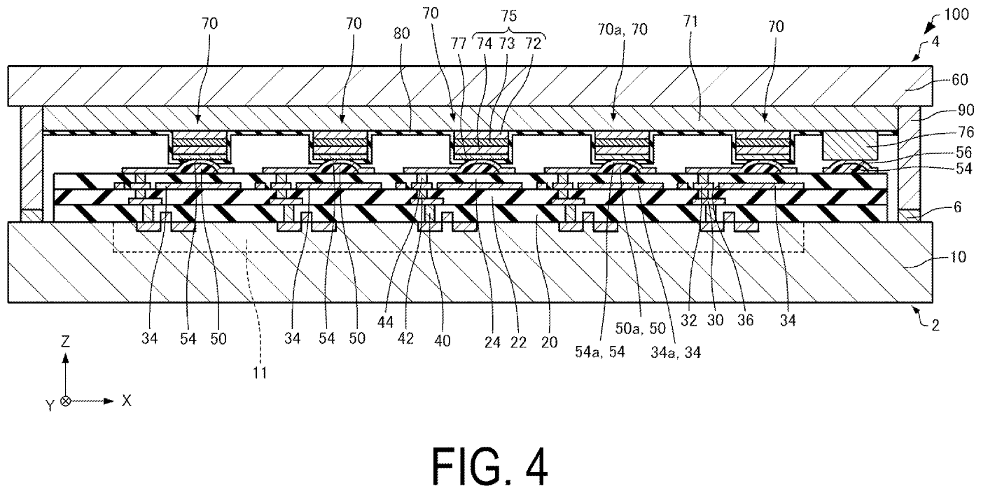

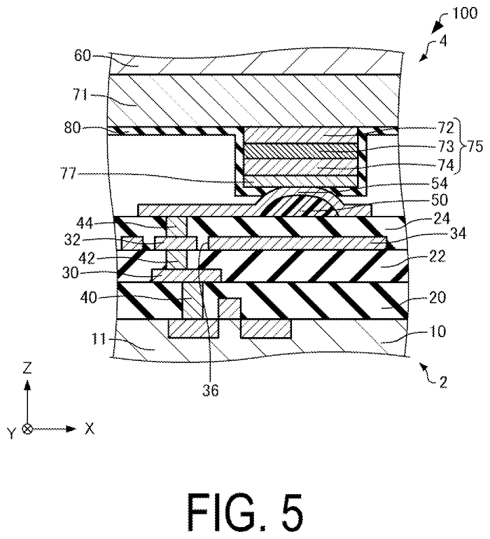

FIG. 4 is a cross-sectional view taken along the line IV-IV in FIG. 1 schematically illustrating the display device 100. FIG. 5 is a diagram in which a portion of FIG. 4 is enlarged. As illustrated in FIGS. 4 and 5, the printed wired board 2 includes, for example, a first substrate 10, insulating layers 20, 22, and 24, wiring layers 30 and 32, a metal layer 34, vias 40, 42, and 44, insulation sections 50 and 52, and conductive layers 54 and 56.

The first substrate 10 is a substrate in which the driving circuit 11 described above is provided on a silicon substrate. Note that, instead of the silicon substrate, it may be possible to use, for example, a glass substrate, a resin substrate, and a ceramic substrate. The transistors 17 and 18 that the driving circuit 11 are, for example, a Metal-Oxide-Semiconductor (MOS) type transistor, a thin membrane transistor, or a field effect transistor. Materials of individual elements and various types of wiring lines of the driving circuit 11 include a conductive material such as polysilicon, metal, metal silicide, or metallic compound, for example.

The insulating layer 20 is provided at the first substrate 10. The wiring layer 30 is provided at the insulating layer 20. The via 40 is provided at a contact hole formed in the insulating layer 20. The via 40 couples the driving circuit 11 and the wiring layer 30.

The insulating layer 22 is provided at the insulating layer 20. The wiring layer 32 is provided at the insulating layer 22. The via 42 is provided at a contact hole formed in the insulating layer 22. The via 42 couples the wiring layer 30 and the wiring layer 32.

The insulating layer 24 is provided at the insulating layer 22. The via 44 is provided at a contact hole formed in the insulating layer 22. The via 44 couples the wiring layer 32 and the conductive layer 54. The insulating layers 20, 22, and 24 are, for example, a silicon oxide layer or a silicon nitride layer. The materials of the wiring layers 30 and 32 are, for example, copper or aluminum. The materials of the vias 40, 42, and 44 are, for example, tungsten, titanium, or titanium nitride.

The metal layer 34 is provided at the insulating layer 22. An opening portion 36 is formed in the metal layer 34. The opening portion 36 extends through the metal layer 34. The wiring layer 32 is provided at the opening portion 36. The metal layer 34 is spaced apart from the wiring layer 32. The metal layer 34 is electrically insulated from the wiring layer 32.

The metal layer 34 is provided between the driving circuit 11 and the light-emitting element 70. The metal layer 34 is provided between the driving circuit 11 and the light-emitting layer 73 of the light-emitting element 70. The metal layer 34 has a light shielding property with respect to light generated at the light-emitting element 70. A constant potential is applied to the metal layer 34. The metal layer 34 may have a ground potential. The material of the metal layer 34 is, for example, copper or aluminum.

A plurality of the metal layers 34 are provided so as to correspond to the plurality of light-emitting elements 70. Of the plurality of metal layers 34, a first metal layer 34a is provided between the driving circuit 11 and a first light-emitting element 70a of the plurality of light-emitting elements 70. Of the plurality of metal layers 34, a second metal layer 34b is provided between the driving circuit 11 and a second light-emitting element 70b of the plurality of light-emitting elements 70, as illustrated in FIG. 1. The first light-emitting element 70a and the second light-emitting element 70b are light-emitting elements 70 adjacent to each other in the Y-axis direction, for example. In the example illustrated in the drawing, the first metal layer 34a and the second metal layer 34b continue with each other. Metal layers 34 adjacent to each other in the X-axis direction are spaced apart from each other. Note that the outer edge of the metal layer 34 is illustrated in FIG. 1.

The insulation section 50 is provided at the insulating layer 24, as illustrated in FIGS. 4 and 5. The insulation section 50 is provided between the first substrate 10 and the light-emitting element 70. The insulation section 50 is provided between the first substrate 10 and the second electrode 77 of the light-emitting element 70. The upper surface of the insulation section 50 has a convex shape, for example. The thickness of the insulation section 50 is, for example, 1 μm. The size of the insulation section 50 in the X-axis direction is, for example, 3 μm.

The insulation section 50 has elasticity. The insulation section 50 is configured to press the conductive layer 54 against the second electrode 77 of the light-emitting element 70. The insulation section 50 biases the conductive layer 54 toward the second electrode 77. The insulation section 50 is, for example, a black matrix having a light shielding property with respect to light generated at the light-emitting element 70. The material of the insulation section 50 includes a material in which carbon is added to a resin such as polyimide, modified polyimide, acrylic resin, phenol resin, epoxy resin, or silicone resin, for example. Adding carbon enables the insulation section 50 to have a light shielding property. The material of the insulation section 50 may be photosensitive resin.

A plurality of the insulation sections 50 are provided so as to correspond to the plurality of light-emitting elements 70. Of the plurality of insulation sections 50, a first insulation section 50a is provided between the first substrate 10 and the first light-emitting element 70a. As illustrated in FIG. 1, of the plurality of insulation sections 50, a second insulation section 50b is provided between the first substrate 10 and the second light-emitting element 70b. In the example illustrated in the drawing, the first insulation section 50a and the second insulation section 50b continue with each other. Insulation sections 50 adjacent to each other in the X-axis direction are spaced apart from each other. Note that, although illustration is not given, the plurality of insulation sections 50 may be spaced apart from each other.

The insulation section 52 is provided at the insulating layer 24, as illustrated in FIG. 4. The insulation section 52 is provided between the first substrate 10 and the first electrode 76 of the light-emitting element 70. The upper surface of the insulation section 52 has a convex shape, for example. The insulation section 52 has elasticity. The insulation section 52 presses the conductive layer 56 against the first electrode 76. The insulation section 52 biases the conductive layer 56 toward the first electrode 76. The material of the insulation section 52 is the same material as the insulation section 50.

The conductive layer 54 is provided above the insulating layer 24, the via 44, and the insulation section 50. The conductive layer 54 is provided between the insulation section 50 and the light-emitting element 70. The conductive layer 54 is provided between the insulation section 50 and the second electrode 77 of the light-emitting element 70. The conductive layer 54 is in contact with the second electrode 77. The conductive layer 54 is pressed against the second electrode 77 by the insulation section 50. The conductive layer 54 couples the second electrode 77 and the via 44. The planar-view shape of the conductive layer 54 is, for example, a rectangular shape. The size of the conductive layer 54 in the X-axis direction is, for example, 5 μm. The size of the conductive layer 54 in the Y-axis direction is, for example, 2 μm.

The conductive layer 54 is electrically coupled to the driving circuit 11 through the vias 40, 42, and 44, and the wiring layers 30 and 32. The material of the conductive layer 54 is, for example, Au, Ag, TiW, Cu, Ni, Pd, Al, Cr, Ti, W, NiCr, or lead-free solder. For example, a layer obtained by stacking a TiW layer and an Au layer in this order from the insulation section 50 is used for the conductive layer 54. The thickness of the TiW layer is, for example, 50 nm. The thickness of the Au layer is, for example, 100 nm. The conductive layer 54 and the insulation section 50 constitute a resin core bump.

A plurality of the conductive layers 54 are provided so as to correspond to the plurality of light-emitting elements 70. The plurality of conductive layers 54 are spaced apart from each other. Of the plurality of conductive layers 54, a first conductive layer 54a is provided between the first insulation section 50a and the second electrode 77 of the first light-emitting element 70a. The first conductive layer 54a is pressed against the second electrode 77 of the first light-emitting element 70a by the first insulation section 50a. As illustrated in FIG. 1, of the plurality of conductive layers 54, a second conductive layer 54b is provided between the second insulation section 50b and the second electrode 77 of the second light-emitting element 70b. The second conductive layer 54b is pressed against the second electrode 77 of the second light-emitting element 70b by the second insulation section 50b.

The conductive layer 56 is provided at the insulating layer 24 and also at the insulation section 52, as illustrated in FIG. 4. The conductive layer 56 is provided between the insulation section 52 and the first electrode 76 of the light-emitting element 70. The conductive layer 56 is in contact with the first electrode 76. The conductive layer 56 is pressed against the first electrode 76 by the insulation section 52. The conductive layer 56 is electrically coupled to the driving circuit 11 through a wiring line that is not illustrated, and the material of the conductive layer 56 is the same material as the conductive layer 54. The conductive layer 56 and the insulation section 52 constitute a resin core bump.

### 1.3. Element Substrate

The element substrate 4 is joined to the printed wired board 2 through a glue layer 6. As illustrated in FIGS. 4 and 5, the element substrate 4 includes, for example, a second substrate 60, the light-emitting element 70, a cover layer 80, and a coupling portion 90.

The second substrate 60 is disposed so as to be opposed to the first substrate 10. In the example illustrated in the drawing, a lower surface of the second substrate 60 is parallel to the upper surface of the first substrate 10. The second substrate 60 allows light generated at the light-emitting element 70 to pass through. The second substrate 60 includes, for example, a silicon substrate, a GaN substrate, a sapphire substrate, a SiC substrate, or the like.

The light-emitting element 70 is provided below the second substrate 60. The light-emitting element 70 is provided between the first substrate 10 and the second substrate 60. The light-emitting element 70 includes a plurality of light-emitting elements. The light-emitting element 70 is, for example, an LED.

The light-emitting element 70 includes, for example, a buffer layer 71, a first semiconductor layer 72, the light-emitting layer 73, a second semiconductor layer 74, the first electrode 76, and the second electrode 77.

The buffer layer 71 is provided below the second substrate 60. The buffer layer 71 is provided between the second substrate 60 and the first semiconductor layer 72. The buffer layer 71 is, for example, a layer common to the plurality of light-emitting elements 70. The buffer layer 71 is provided continuously over adjacent light-emitting elements 70. The buffer layer 71 has a first conductive type. The buffer layer 71 is, for example, an n-type GaN layer in which Si is doped.

The first semiconductor layer 72 is provided below the buffer layer 71. The first semiconductor layer 72 is provided between the buffer layer 71 and the light-emitting layer 73. The first semiconductor layer 72 may be provided integrally with the buffer layer 71. The first semiconductor layer 72 has the first conductive type. The first semiconductor layer 72 is, for example, an n-type GaN layer in which Si is doped. For example, the first semiconductor layer 72, the light-emitting layer 73, and the second semiconductor layer 74 are group III nitrides semiconductors, and have a wurtzite-type crystal structure.

The first semiconductor layer 72, the light-emitting layer 73, and the second semiconductor layer 74 are respectively provided for each of the plurality of light-emitting elements 70. In terms of light-emitting elements 70 adjacent to each other, first semiconductor layers 72 are spaced apart from each other, light-emitting layers 73 are spaced apart from each other, and second semiconductor layers 74 are spaced apart from each other. The first semiconductor layer 72, the light-emitting layer 73, and the second semiconductor layer 74 constitute a column portion 75 protruding downward from the buffer layer 71. The size of the column portion 75 in the X-axis direction is, for example, 3 μm. The size of the column portion 75 in the Y-axis direction is, for example, 3 μm.

The light-emitting layer 73 is provided below the first semiconductor layer 72. The light-emitting layer 73 is provided between the first semiconductor layer 72 and the second semiconductor layer 74. The light-emitting layer 73 has an i-type conductivity type in which any impurity is intentionally not doped. With a current being injected, the light-emitting layer 73 generates light. The light-emitting layer 73 includes, for example, a well layer and a barrier layer. The well layer and the barrier layer are i-type semiconductor layers. The well layer is, for example, an InGaN layer. The barrier layer is, for example, a GaN layer. The light-emitting layer 73 has a multiple quantum well (MQW) structure including the well layer and the barrier layer.

Note that there is no limitation as to the numbers of well layers and the barrier layers that constitute the light-emitting layer 73. For example, it may be possible to employ a configuration in which only one layer of well layer is provided. In this case, the light-emitting layer 73 has a single quantum well (SQW) structure.

The second semiconductor layer 74 is provided below the light-emitting layer 73. The second semiconductor layer 74 is provided between the light-emitting layer 73 and the second electrode 77. The second semiconductor layer 74 has a second conductive type differing from the first conductive type. For example, the second semiconductor layer 74 is a p-type GaN layer in which Mg is doped.

The light-emitting element 70 is configured as a PIN diode comprised of the p-type second semiconductor layer 74, the i-type light-emitting layer 73, and the n-type first semiconductor layer 72. In the light-emitting element 70, when a forward-bias voltage for the PIN diode is applied across the first electrode 76 and the second electrode 77, a current is injected into the light-emitting layer 73 to cause recombination between an electron and a hole in the light-emitting layer 73. With this recombination, the light-emitting layer 73 generates light. The plurality of light-emitting elements 70 may generate color lights having the same color, or may generate color lights having different colors. The plurality of light-emitting elements 70 may generate red color light, green color light, and blue color light. This enables the display device 100 to achieve full-color display.

The first electrode 76 is provided below the buffer layer 71. The first electrode 76 is provided between the buffer layer 71 and the conductive layer 56. The buffer layer 71 may be in ohmic contact with the first electrode 76. The first electrode 76 is joined, for example, to the conductive layer 56. The first electrode 76 is electrically coupled to the first semiconductor layer 72 through the buffer layer 71. The first electrode 76 is electrically coupled to the driving circuit 11 through the conductive layer 56 and a wiring line that is not illustrated. The first electrode 76 serves as an electrode common to the plurality of light-emitting elements 70, for example.

For example, an electrode obtained by stacking a Cr layer, an Ni layer, an Au layer in this order from the buffer layer 71 side is used for the first electrode 76. The first electrode 76 may have a ground potential. The first electrode 76 serves as one electrode used to inject a current into the light-emitting layer 73.

The second electrode 77 is provided below the second semiconductor layer 74. The second electrode 77 is provided between the second semiconductor layer 74 and the conductive layer 54. The second semiconductor layer 74 may be in ohmic contact with the second electrode 77. The second electrode 77 is joined to the conductive layer 54, for example. The second electrode 77 is electrically coupled to the driving circuit 11 through the conductive layer 54, the vias 40, 42, and 44, and the wiring layers 30 and 32. The second electrode 77 is provided for each of the plurality of light-emitting elements 70. In terms of light-emitting elements 70 adjacent to each other, second electrodes 77 are spaced apart from each other. The second electrode 77 reflects, toward the second substrate 60, light generated at the light-emitting element 70. This enables the display device 100 to output light from the second substrate 60 side.

For example, an electrode obtained by stacking an Ni layer and an Au layer in this order from the second semiconductor layer 74 side is used for the second electrode 77. The second electrode 77 serves as the other electrode used to inject a current into the light-emitting layer 73.

The cover layer 80 is provided at the lower surface of the buffer layer 71, side surfaces of the column portion 75, side surfaces of the second electrode 77, and the lower surface of the second electrode 77. The cover layer 80 covers the light-emitting elements 70. The cover layer 80 protects the light-emitting elements 70. The cover layer 80 is, for example, a silicon oxide layer or a silicon nitride layer.

The coupling portion 90 is provided between the first substrate 10 and the second substrate 60. The coupling portion 90 couples the first substrate 10 and the second substrate 60. The coupling portion 90 is joined to the first substrate 10 through the glue layer 6. As illustrated in FIG. 1, the coupling portion 90 surrounds the plurality of light-emitting elements 70 as viewed from the Z-axis direction. The planar-view shape of the coupling portion 90 is, for example, a frame shape that surrounds the plurality of light-emitting elements 70. The material of the coupling portion 90 is, for example, a metal such as Al. For example, a constant potential is applied to the coupling portion 90. The coupling portion 90 may have a ground potential.

Note that, although the InGaN-based light-emitting layer 73 has been described, the light-emitting layer 73 may employ various types of base materials that make it possible to emit light when a current is injected, in accordance with the wavelength of light to be outputted. For example, it may be possible to employ semiconductor materials that are AlGaN based, AlGaAs based, InGaAs based, InGaAsP based, InP based, GaP based, AlGaP based, and the like.

In addition, description has been made such that the first conductive type is an n-type and the second conductive type is a p-type. However, it may be possible to employ a configuration in which the first conductive type is a p-type and the second conductive type is an n-type.

Furthermore, although illustration is not given, the column portion 75 of the light-emitting element 70 may include a plurality of nano-structural bodies.

### 1.4. Operation and Effects

The display device 100 includes: the first substrate 10; the second substrate 60 disposed so as to be opposed to the first substrate 10; the first light-emitting element 70a and the second light-emitting element 70b provided between the first substrate 10 and the second substrate 60; and the driving circuit 11 provided at the first substrate 10 and configured to drive the first light-emitting element 70a and the second light-emitting element 70b. In addition, the display device 100 includes: the first insulation section 50a having elasticity and provided between the first substrate 10 and the first light-emitting element 70a; and the second insulation section 50b having elasticity and provided between the first substrate 10 and the second light-emitting element 70b. Furthermore, the display device 100 includes: the first conductive layer 54a provided between the first insulation section 50a and the first light-emitting element 70a, the first conductive layer 54a being configured to be electrically coupled to the driving circuit 11 and be pressed against the first light-emitting element 70a by the first insulation section 50a; and the second conductive layer 54b provided between the second insulation section 50b and the second light-emitting element 70b, the second conductive layer 54b being configured to be electrically coupled to the driving circuit 11 and be pressed against the second light-emitting element 70b by the second insulation section 50b. In addition, the display device 100 includes the coupling portion 90 configured to couple the first substrate 10 and the second substrate 60.

Thus, with the display device 100, even when the heights of the light-emitting elements 70a and 70b vary, the insulation sections 50a and 50b deform. Thus, it is possible to maintain the contact between the first conductive layer 54a and the first light-emitting element 70a and the contact between the second conductive layer 54b and the second light-emitting element 70b. This makes it possible to reduce a possibility of a failure occurring in the electrical coupling between the driving circuit 11 and the light-emitting elements 70a and 70b. Thus, it is possible to improve reliability of electrical coupling between the driving circuit 11 and the light-emitting elements 70a and 70b.

For example, in some cases, a warp occurs in the second substrate 60 due to heat of the light-emitting elements 70a and 70b, and variations may occur in the heights of the light-emitting element 70a, 70b. Specifically, variations may occur in the positions of the second electrodes 77 of the light-emitting elements 70a and 70b in the Z-axis direction. Even in such a case, in the display device 100, the insulation sections 50a and 50b deform, which makes it possible to reduce a possibility of a failure occurring in the electrical coupling between the driving circuit 11 and the light-emitting elements 70a and 70b.

In the display device 100, a constant potential is applied to the coupling portion 90. Thus, with the display device 100, it is possible to reduce an electromagnetic wave noise entering the light-emitting elements 70a and 70b.

In the display device 100, the coupling portion 90 surrounds the first light-emitting element 70a and the second light-emitting element 70b. Thus, with the display device 100, it is possible to further reduce an electromagnetic wave noise entering the light-emitting elements 70a and 70b.

In the display device 100, the first insulation section 50a and the second insulation section 50b continue with each other. Thus, with the display device 100, it is possible to reduce the size thereof, as compared with a case in which the first insulation section 50a and the second insulation section 50b are separate. Specifically, it is possible to reduce the size of the display device 100 in the Y-axis direction. In addition, the insulation section including the first insulation section 50a and the second insulation section 50b continuously provided overlaps with the data line 13 so as to be along the data line 13 as viewed from the Z-axis direction, for example. Thus, it is possible to enhance the uniformity of stress acting on the data line 13, as compared with, for example, a case in which the first insulation section 50a and the second insulation section 50b are separate from each other.

In the display device 100, the first insulation section 50a and the second insulation section 50b have a light shielding property. This enables the display device 100 to prevent the light generated at the light-emitting elements 70a and 70b from entering the driving circuit 11. Thus, it is possible to prevent malfunction of the driving circuit 11.

The display device 100 includes: the first metal layer 34a having a light shielding property and provided between the first light-emitting element 70a and the driving circuit 11; and the second metal layer 34b having a light shielding property and provided between the second light-emitting element 70b and the driving circuit 11. This enables the display device 100 to prevent the light generated at the light-emitting elements 70a and 70b from entering the driving circuit 11. Thus, it is possible to prevent malfunction of the driving circuit 11.

In the display device 100, a constant potential is applied to the first metal layer 34a and the second metal layer 34b. Thus, with the display device 100, it is possible to reduce the electromagnetic wave noise entering the driving circuit 11.

### 2. Method of Manufacturing Display Device

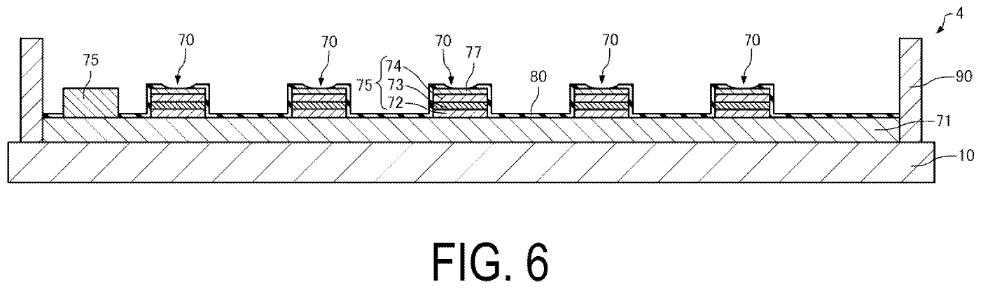

Next, a method of manufacturing the display device 100 according to the present embodiment will be described with reference to the drawings. FIG. 6 is a cross-sectional view schematically illustrating a step of manufacturing the display device 100 according to the present embodiment.

As illustrated in FIG. 6, the buffer layer 71 is caused to epitaxially grow at the second substrate 60. The method of epitaxially growing includes, for example, a metal organic chemical vapor deposition (MOCVD) method, a molecular beam epitaxy (MBE) method, or the like.

Next, a mask layer that is not illustrated is formed at the buffer layer 71. The mask layer is formed, for example, through an electron-beam vapor deposition method or a sputtering method or the like.

Next, by using the mask layer as a mask, the first semiconductor layer 72, the light-emitting layer 73, and the second semiconductor layer 74 are caused to epitaxially grow at the buffer layer 71 in this order. The method of epitaxially growing includes, for example, an MOCVD method, an MBE method, or the like. Next, the mask layer (not illustrated) is removed, for example. Note that the mask layer may not be removed, and may be left as it is. Through this step, the column portion 75 is formed.

Note that it may be possible to employ a configuration in which the column portion 75 is formed without using a mask layer such that the first semiconductor layer 72, the light-emitting layer 73, and the second semiconductor layer 74 are caused to epitaxially grow subsequent to the formation of the buffer layer 71, and patterning is applied to the semiconductor layers 72 and 74 and the light-emitting layer 73 that have been grown. The patterning is performed, for example, through photolithography and etching.

Next, the second electrode 77 is formed at the second semiconductor layer 74. The second electrode 77 is formed, for example, through a sputtering method, a chemical vapor deposition (CVD) method, or vacuum deposition.

Next, the cover layer 80 is formed at the buffer layer 71 and at the second electrode 77. The cover layer 80 is formed, for example, through a CVD method. Next, the cover layer 80 is patterned into a predetermined shape. The patterning is performed, for example, through photolithography and etching.

Next, the first electrode 76 is formed at the buffer layer 71. The first electrode 76 is formed, for example, through a sputtering method, a CVD method, or vacuum deposition. Note that there is no particular limitation as to the order of the step of forming the first electrode 76 and the step of forming the second electrode 77.

Through these steps, the plurality of light-emitting elements 70 are formed.

Next, the coupling portion 90 is formed at the second substrate 60. The coupling portion 90 is formed, for example, through a plating method or a sputtering method. Note that the coupling portion 90 may be formed before the light-emitting element 70 is formed.

Through this step, the element substrate 4 is formed.

As illustrated in FIG. 4, the element substrate 4 is junction-down mounted at the printed wired board 2. The coupling portion 90 is joined to the first substrate 10 with the glue layer 6. The first electrode 76 is joined to the conductive layer 56. The second electrode 77 is joined to the conductive layer 54. Note that the printed wired board 2 is manufactured using a semiconductor manufacturing process.

Through these steps, it is possible to manufacture the display device 100.

### 3. Modification Example of Display Device

### 3.1. First Modification Example

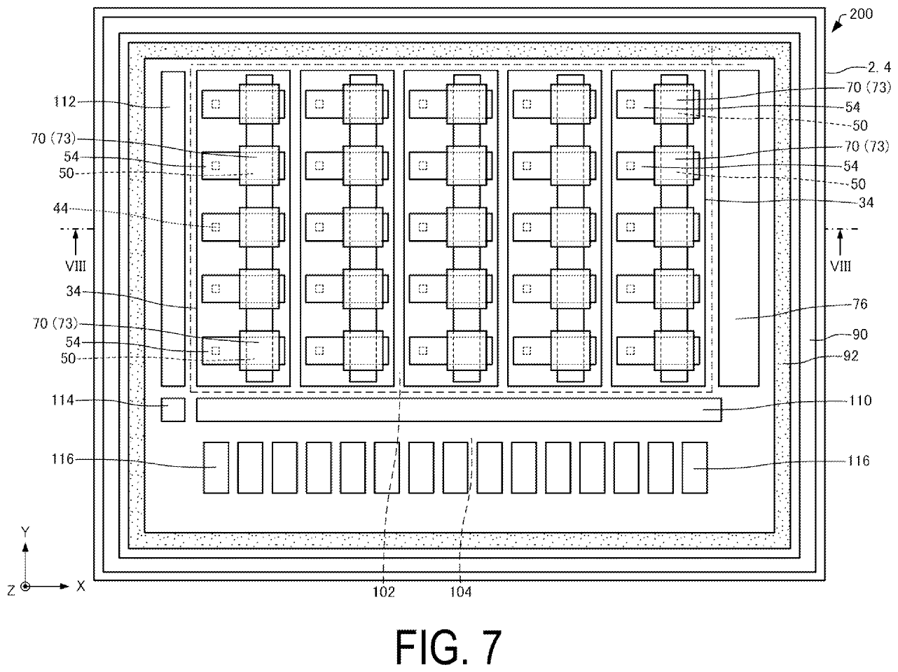

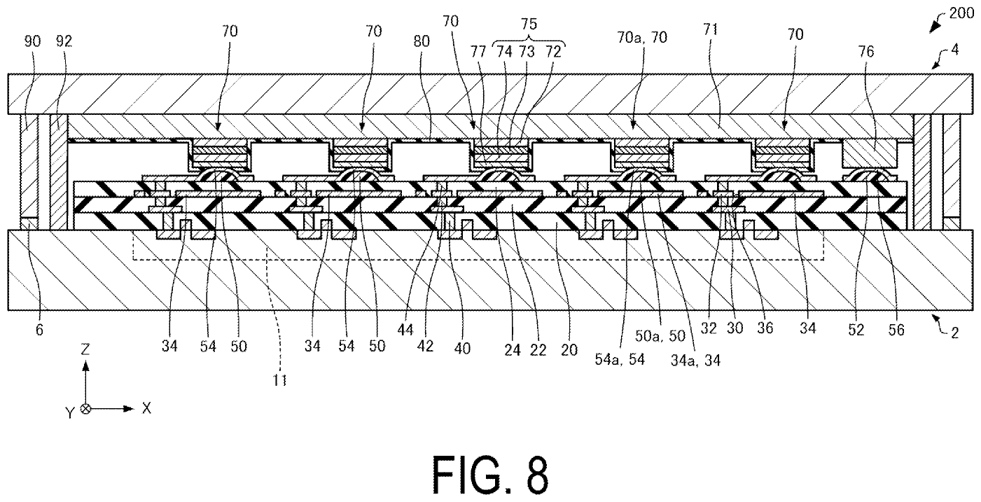

Next, a display device according to a first modification example of the present embodiment will be described with reference to the drawings. FIG. 7 is a plan view schematically illustrating a display device 200 according to the first modification example of the present embodiment. FIG. 8 is a cross-sectional view taken along the line VIII-VIII in FIG. 7 schematically illustrating the display device 200 according to the first modification example of the present embodiment.

Below, in the display device 200 according to the first modification example of the present embodiment, the same reference characters are attached to members having functions similar to the component members of the display device 100 according to the present embodiment described above, and detailed explanation thereof will not be repeated. This similarly applies to display devices according to the second and third modification examples according to the present embodiment that will be described later.

The display device 200 differs from the display device 100 described above in that a spacer member 92 is provided as illustrated in FIGS. 7 and 8.

The spacer member 92 is provided between the first substrate 10 and the second substrate 60 as illustrated in FIG. 8. The spacer member 92 is in contact with the first substrate 10 and the second substrate 60. The spacer member 92 surrounds the plurality of light-emitting elements 70 as viewed from the Z-axis direction as illustrated in FIG. 7. The planar-view shape of the spacer member 92 is, for example, a frame shape that surrounds the plurality of light-emitting elements 70. The spacer member 92 is provided inside of the coupling portion 90.

The material of the spacer member 92 is, for example, a metal such as Al. For example, a constant potential is applied to the spacer member 92. This configuration makes it possible to reduce an electromagnetic wave noise entering the light-emitting elements 70a and 70b. The spacer member 92 may have a ground potential. Note that, although illustration is not given, the spacer member 92 may be provided outside of the coupling portion 90.

The display device 200 includes the spacer member 92 provided between the first substrate 10 and the second substrate 60 and being in contact with the first substrate 10 and the second substrate 60. In addition, the spacer member 92 surrounds the first light-emitting element 70a and the second light-emitting element 70b. Furthermore, the coupling portion 90 is joined to the first substrate 10 through the glue layer 6. Thus, with the display device 200, the spacer member 92 makes it possible to enhance the degree of being parallel between the first substrate 10 and the second substrate 60. Since the spacer member 92 is not joined to the substrate 10 or 60 with a glue layer, it is easy to enhance the degree of being parallel between the first substrate 10 and the second substrate 60.

### 3.2. Second Modification Example

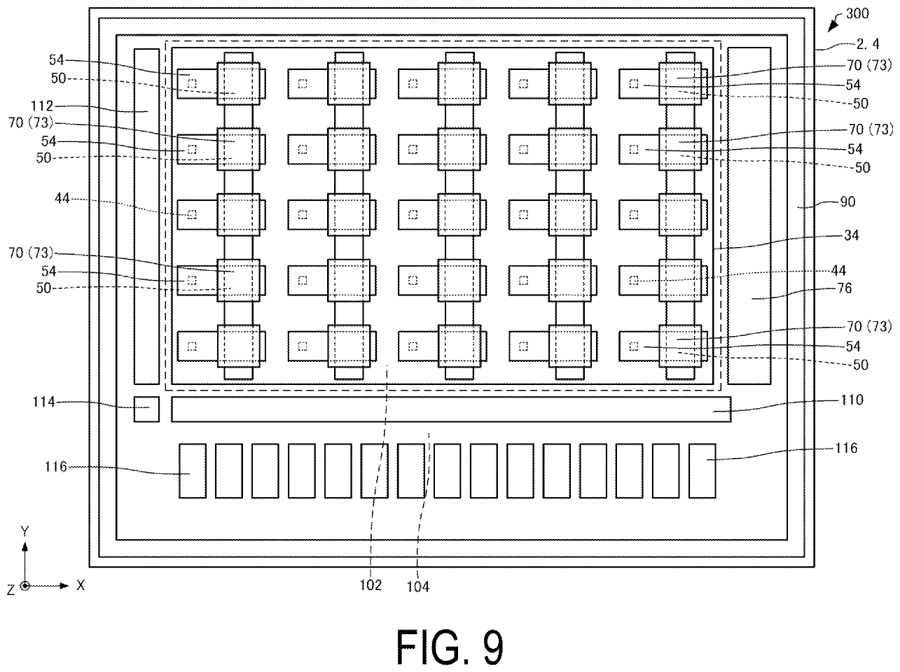

Next, a display device according to a second modification example of the present embodiment will be described with reference to the drawings. FIG. 9 is a plan view schematically illustrating a display device 300 according to the second modification example of the present embodiment.

In a case of the display device 100 described above, metal layers 34 adjacent in the X-axis direction are spaced apart from each other as illustrated in FIG. 1.

In contrast, in the display device 300, metal layers 34 adjacent in the X-axis direction continue with each other as illustrated in FIG. 9. The plurality of metal layers 34 constitute a common metal layer 34. Thus, with the display device 300, it is possible to further reduce the light entering the driving circuit 11.

### 3.3. Third Modification Example

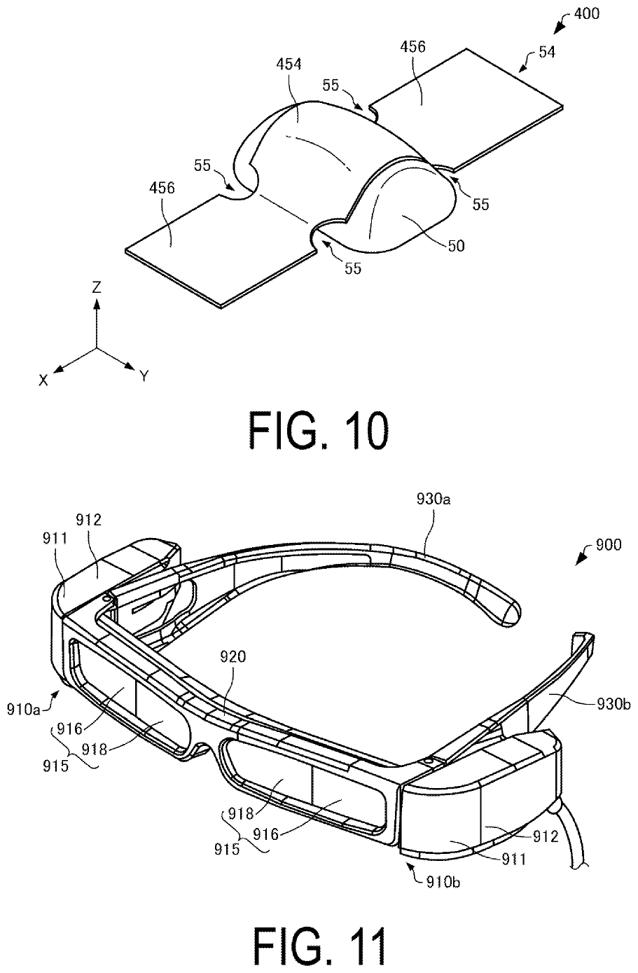

Next, a display device according to a third modification example of the present embodiment will be described with reference to the drawings. FIG. 10 is a perspective view schematically illustrating an insulation section 50 and a conductive layer 54 of a display device 400 according to the third modification example of the present embodiment.

In a case of the display device 100 described above, the planar-view shape of the conductive layer 54 is a rectangular shape, as illustrated in FIG. 1.

In contrast, in a case of the display device 400, a cutout 55 is formed in the conductive layer 54, as illustrated in FIG. 10.

The cutout 55 is formed at a position that overlaps with the outer edge of the insulation section 50 as viewed from the Z-axis direction. In the example illustrated in the drawing, four cutouts 55 are formed in one conductive layer 54. The cutout 55 makes it possible to alleviate stress occurring between a first section 454 and a second section 456 of the conductive layer 54. The first section 454 is provided at the insulation section 50, and is a portion that elastically deforms together with the insulation section 50. The second section 456 is a portion provided at the insulating layer 24. Two second sections 456 are provided. The first section 454 is interposed between two second sections 456 as viewed from the Z-axis direction. The cutout 55 makes it possible to suppress occurrence of a crack in the conductive layer 54.

The cutout 55 overlaps with the metal layer 34 as viewed from the Z-axis direction. This makes it possible to reduce a possibility that light that has passed through the cutout 55 enters the driving circuit 11. This makes it possible to suppress malfunction of the driving circuit 11.

### 4. Electronic Apparatus

### 4.1. Overall Configuration

Next, a head-mounted display serving as an electronic apparatus according to the present embodiment will be described with reference to the drawings. FIG. 11 is a perspective view schematically illustrating a head-mounted display 900 according to the present embodiment.

The head-mounted display 900 is a head mounted-type display having an outer appearance of eyeglasses, as illustrated in FIG. 11. The head-mounted display 900 is mounted on the head of a viewer. The viewer represents a user who uses the head-mounted display 900. The head-mounted display 900 allows the viewer to visually recognize imaging light of a virtual image and to visually recognize an external image in a see-through manner.

The head-mounted display 900 includes, for example, a first display unit 910a, a second display unit 910b, a frame 920, a first temple 930a, and a second temple 930b.

The first display unit 910a and the second display unit 910b display images. Specifically, the first display unit 910a displays a virtual image for a right eye of the viewer. The second display unit 910b displays a virtual image for a left eye of the viewer. The display units 910a, and 910b each include, for example, an image forming device 911 and a light-guiding device 915.

The image forming device 911 forms image light. The image forming device 911 includes, for example, an optical system such as a light source and a projection device, and an external member 912. The external member 912 accommodates the light source and the projection device.

The light-guiding device 915 covers the front of the viewer. The light-guiding device 915 guides the imaging light formed at the image forming device 911, and superimposes the external light and the imaging light to cause the viewer to visually recognize it. Note that details of the image forming device 911 and the light-guiding device 915 will be described later.

The frame 920 supports the first display unit 910a and the second display unit 910b. The frame 920 supports the display units 910a and 910b, for example. In the example illustrated in the drawing, the image forming device 911 of the first display unit 910a is attached to one end portion of the frame 920. The image forming device 911 of the second display unit 910b is attached to the other end portion of the frame 920.

The first temple 930a and the second temple 930b extend from the frame 920. In the example illustrated in the drawing, the first temple 930a extends from one end portion of the frame 920. The second temple 930b extends from the other end portion of the frame 920.

The first temple 930a and the second temple 930b are put over the ears of the viewer when the viewer wears the head-mounted display 900. The head of the viewer is placed between the temples 930a and 930b.

### 4.2. Image Forming Device and Light-Guiding Device

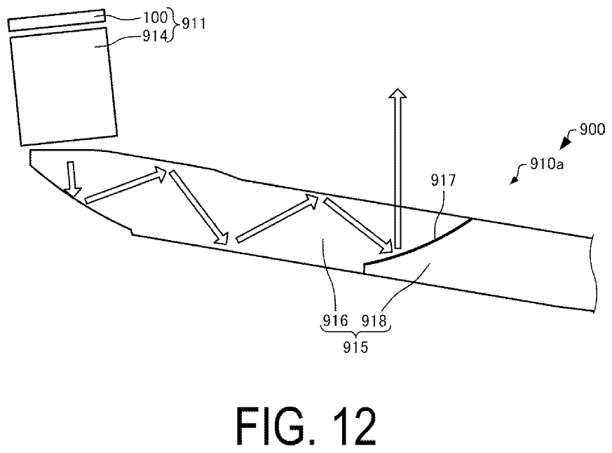

FIG. 12 is a diagram schematically illustrating the image forming device 911 and the light-guiding device 915 in the first display unit 910a of the head-mounted display 900. Note that the first display unit 910a and the second display unit 910b basically have the same configuration. Thus, the description of the first display unit 910a below can be applied to the second display unit 910b.

The image forming device 911 includes, for example, the display device 100 serving as a light source and a projection device 914 for image formation, as illustrated in FIG. 12.

The projection device 914 projects, toward the light-guiding device 915, the imaging light outputted from the display device 100. The projection device 914 is, for example, a projection lens. The lens constituting the projection device 914 may employ a lens having a lens surface including an axially symmetric surface.

For example, the light-guiding device 915 is screwed to a lens barrel of the projection device 914, thereby being accurately positioned with respect to the projection device 914. The light-guiding device 915 includes, for example, an imaging-light guiding member 916 configured to guide the imaging light, and a see-through member 918 for see-through view.

The imaging light outputted from the projection device 914 enters the imaging-light guiding member 916. The imaging-light guiding member 916 is a prism configured to guide the imaging light toward the eye of the viewer. The imaging light that enters the imaging-light guiding member 916 repeats reflection on the inner surfaces of the imaging-light guiding member 916, and then is reflected on a reflection layer 917 to be outputted from the imaging-light guiding member 916. The imaging light outputted from the imaging-light guiding member 916 reaches the eye of the viewer. The reflection layer 917 is comprised, for example, of a metal or a dielectric multilayer film. The reflection layer 917 may be a half mirror.

The see-through member 918 is adjacent to the imaging-light guiding member 916. The see-through member 918 is fixed to the imaging-light guiding member 916. The outer surface of the see-through member 918 is continuous with the outer surface of the imaging-light guiding member 916, for example. The see-through member 918 allows the viewer to see through the external light. The imaging-light guiding member 916 also has the function of allowing the viewer to see the external light therethrough, in addition to the function of guiding the imaging light. Note that the head-mounted display 900 may be configured so as not to allow the viewer to see through the external light.

The electronic apparatus according to the present embodiment is not limited to the head-mounted display as long as the display device described above is included. The electronic apparatus according to the present embodiment may be an electronic view finder (EVF), a projector, a wearable display such as a smart watch, or a vehicle head-up display.

The present embodiment and the modification examples described above are merely examples, and are not given for the purpose of limitation to these. For example, it is possible to combine the embodiment and the modification examples as appropriate.

The present disclosure includes configurations that are substantially identical to the configurations described in the embodiment, for example, configurations with identical functions, methods, and results, or configurations with identical objects and effects. In addition, the present disclosure includes configurations obtained by replacing non-essential portions of the configurations described in the embodiment. In addition, the present disclosure includes configurations having the same operations and effects or configurations making it possible to achieve the same objects as those of the configurations described in the embodiment. Furthermore, the present disclosure includes configurations obtained by adding known techniques to the configurations described in the embodiment.

The following items are derived from the embodiment and the modification examples described above.

One aspect of a display device includes:
a first substrate;
a second substrate disposed so as to be opposed to the first substrate;
a first light-emitting element and a second light-emitting element provided between the first substrate and the second substrate;
a driving circuit provided at the first substrate and configured to drive the first light-emitting element and the second light-emitting element;
a first insulation section having elasticity and provided between the first substrate and the first light-emitting element;
a second insulation section having elasticity and provided between the first substrate and the second light-emitting element;
a first conductive layer provided between the first insulation section and the first light-emitting element, the first conductive layer being configured to be electrically coupled to the driving circuit and be pressed against the first light-emitting element by the first insulation section;
a second conductive layer provided between the second insulation section and the second light-emitting element, the second conductive layer being configured to be electrically coupled to the driving circuit and be pressed against the second light-emitting element by the second insulation section; and
a coupling portion configured to couple the first substrate and the second substrate.

With this display device, it is possible to reduce a possibility of a failure occurring in the electrical coupling between the driving circuit and the first light-emitting element as well as in the electrical coupling between the driving circuit and the second light-emitting element.

In the aspect of the display device, a constant potential may be applied to the coupling portion.

With this display device, it is possible to reduce an electromagnetic wave noise entering the first light-emitting element and the second light-emitting element.

In the aspect of the display device, the coupling portion may surround the first light-emitting element and the second light-emitting element.

With this display device, it is possible to further reduce an electromagnetic wave noise entering the first light-emitting element and the second light-emitting element.

In the aspect of the display device, the first insulation section and the second insulation section may continue with each other.

With this display device, it is possible to reduce the size thereof.

In the aspect of the display device, the first insulation section and the second insulation section may have a light shielding property.

With this display device, it is possible to prevent light generated at the first light-emitting element and the second light-emitting element from entering the driving circuit.

The display device according to the aspect may include:
a first metal layer provided between the first light-emitting element and the driving circuit and having a light shielding property; and
a second metal layer provided between the second light-emitting element and the driving circuit and having a light shielding property.

With this display device, it is possible to prevent light generated at the first light-emitting element and the second light-emitting element from entering the driving circuit.

In the aspect of the display device, a constant potential may be applied to the first metal layer and the second metal layer.

With this display device, it is possible to reduce an electromagnetic wave noise entering the driving circuit.

The display device according to the aspect may include:
a spacer member provided between the first substrate and the second substrate and being in contact with the first substrate and the second substrate, in which
the spacer member surrounds the first light-emitting element and the second light-emitting element, and
the coupling portion is joined to the first substrate through a glue layer.

With this display device, the spacer member makes it possible to enhance the degree of being parallel between the first substrate and the second substrate.

One aspect of an electronic apparatus includes the aspect of the display device.

What is claimed is:

1. A display device, comprising:
a first substrate;
a second substrate disposed so as to be opposed to the first substrate;
a first light-emitting element and a second light-emitting element provided between the first substrate and the second substrate;
a driving circuit provided at the first substrate and configured to drive the first light-emitting element and the second light-emitting element;
a first insulation section having elasticity and provided between the first substrate and the first light-emitting element;
a second insulation section having elasticity and provided between the first substrate and the second light-emitting element;
a first conductive layer provided between the first insulation section and the first light-emitting element, the first conductive layer being configured to be electrically coupled to the driving circuit and be pressed against the first light-emitting element by the first insulation section;
a second conductive layer provided between the second insulation section and the second light-emitting element, the second conductive layer being configured to be electrically coupled to the driving circuit and be pressed against the second light-emitting element by the second insulation section; and
a coupling portion configured to couple the first substrate and the second substrate.

2. The display device according to claim 1, wherein a constant potential is applied to the coupling portion.

3. The display device according to claim 2, wherein the coupling portion surrounds the first light-emitting element and the second light-emitting element.

4. The display device according to claim 1, wherein the first insulation section and the second insulation section continue with each other.

5. The display device according to claim 1, wherein the first insulation section and the second insulation section have a light shielding property.

6. The display device according to claim 1 comprising:
a first metal layer provided between the first light-emitting element and the driving circuit and having a light shielding property; and
a second metal layer provided between the second light-emitting element and the driving circuit and having a light shielding property.

7. The display device according to claim 6, wherein a constant potential is applied to the first metal layer and the second metal layer.

8. The display device according to claim 1, further comprising:
a spacer member provided between the first substrate and the second substrate and being in contact with the first substrate and the second substrate, wherein
the spacer member surrounds the first light-emitting element and the second light-emitting element, and
the coupling portion is joined to the first substrate through a glue layer.

9. An electronic apparatus, comprising the display device according to claim 1.
